(19) United States
(12) Patent Application Publication
(10) Pub. No.: US 2026/0155174 A1
(43) Pub. Date: Jun. 4, 2026

(54) MEMORY APPARATUS AND OPERATION METHOD OF MEMORY APPARATUS

(71) Applicant: SK hynix Inc., Icheon-si (KR)

(72) Inventors: In Seon YEO, Icheon-si (KR); Moo Hui PARK, Icheon-si (KR); Gap Sok DO, Icheon-si (KR)

(21) Appl. No.: 19/197,164

(22) Filed: May 2, 2025

(30) Foreign Application Priority Data
Nov. 29, 2024 (KR) 10-2024-0175292

(51) Int. Cl. G11C 13/00

(52) U.S. Cl. CPC G11C 13/003; G11C 13/0038; G11C 13/004; G11C 13/0097

(57) ABSTRACT

A memory apparatus includes: a cell array comprising a plurality of memory cells, and an access circuit that performs a read operation on a memory cell among the plurality of memory cells. Such an access circuit determines data stored in the memory cell and selectively applies a reverse pulse to the memory cell based on the determined data of the memory cell.

### CROSS-REFERENCE TO RELATED APPLICATION

This application claims priority under 35 U.S.C. § 119(a) to Korean Patent Application No. 10-2024-0175292 filed on Nov. 29, 2024, which is incorporated herein by reference in its entirety.

### BACKGROUND

### 1. Technical Field

Embodiments of the present disclosure relate to an integrated circuit technology, and, to a memory apparatus and an operation method thereof.

### 2. Related Art

Recently, with the miniaturization, low power consumption, high performance, and diversification of electronic devices, memories capable of storing information in various electronic appliances such as computers and portable communication devices are desirable. In addition, research on memories having various characteristics is also ongoing.

Memories under research include memories that can store data by using the characteristic of switching between different resistance states depending on a voltage or a current applied. Such memories include a resistive random access memory (RRAM), a phase-change random access memory (PRAM), a ferroelectric random access memory (FRAM), a magnetic random access memory (MRAM), an e-fuse, and the like.

### SUMMARY

In an embodiment, a memory apparatus may include: a cell array including a plurality of memory cells; and an access circuit that performs a read operation on a memory cell among the plurality of memory cells. The access circuit determines data stored in the memory cell and selectively applies a reverse pulse to the memory cell based on the determined data of the memory cell.

In another embodiment, a memory apparatus may include: a cell array including at least one memory cell electrically connected between a bit line and a word line; a voltage changing circuit that provides voltages to a global bit line electrically connected to the bit line and a global word line electrically connected to the word line; and a control circuit that selects a voltage to be provided to the global word line and a voltage to be provided to the global bit line from the voltages by controlling the voltage changing circuit according to a command, write data, and read data.

In an embodiment, an operation method of a memory apparatus may include: receiving a read command to read a memory cell; sensing data stored in the memory cell according to the read command; determining whether the sensed data of the memory cell is reset data; and providing a reverse pulse to the memory cell in response to determining that the data stored in the memory cell is the reset data.

### BRIEF DESCRIPTION OF THE DRAWINGS

FIGS. 1 and 2 are diagrams for illustrating a write operation of a memory apparatus in accordance with an embodiment of the present disclosure.

FIGS. 3 and 4 are diagrams for illustrating a read operation of the memory apparatus in accordance with the embodiment of the present disclosure.

FIG. 5 is a diagram for illustrating a change in a threshold voltage of a memory cell due to a read operation of the memory apparatus in accordance with an embodiment of the present disclosure.

FIG. 6 is a diagram for illustrating configuration of a memory apparatus in accordance with an embodiment of the present disclosure.

FIG. 7 is a diagram for illustrating configuration of a voltage changing circuit of a memory apparatus in accordance with an embodiment of the present disclosure.

FIGS. 8 and 9 are timing diagrams for illustrating an operation of a memory apparatus in accordance with an embodiment of the present disclosure.

FIG. 10 is a flowchart for illustrating an operation of a memory apparatus in accordance with an embodiment of the present disclosure.

### DETAILED DESCRIPTION

Various embodiments are directed to providing a memory apparatus for reducing a change in a threshold voltage of a memory cell in a reset state caused by read disturbance, and an operation method thereof.

The data storage reliability of a memory cell can be improved.

Hereafter, some embodiments of the present disclosure will be described with reference to the accompanying drawings.

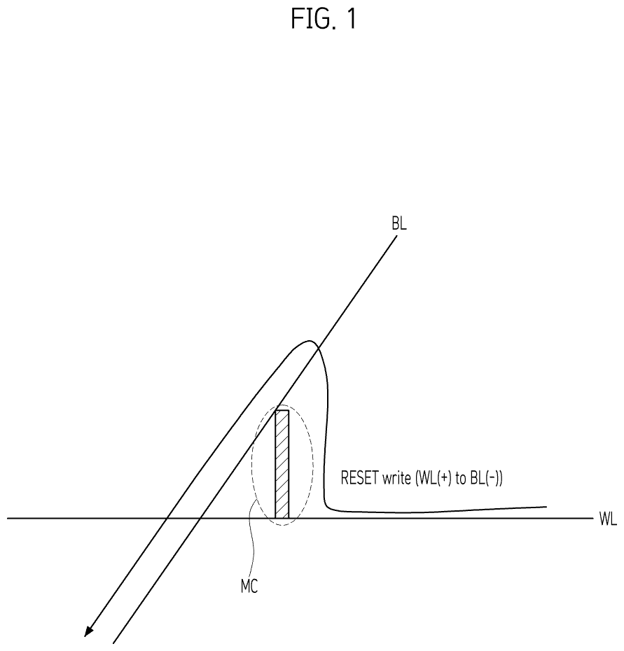

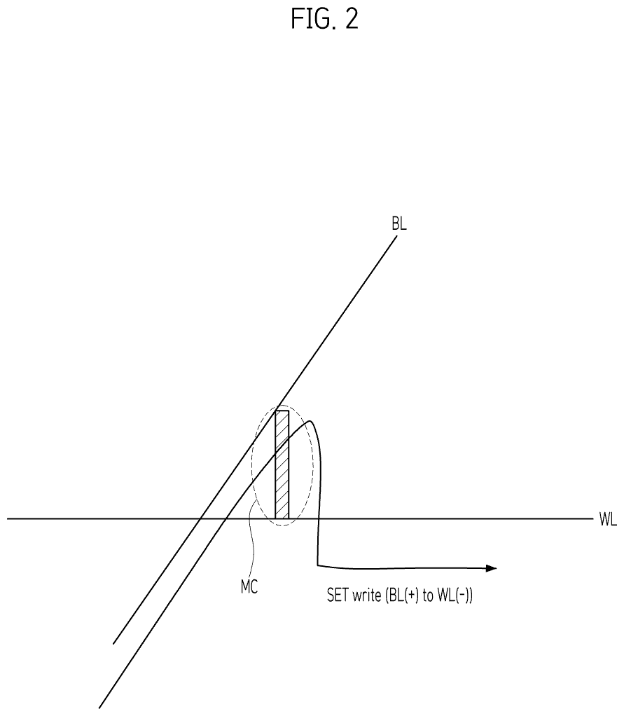

FIGS. 1 and 2 are diagrams for illustrating a write operation of a memory apparatus in accordance with an embodiment of the present disclosure.

FIG. 1 is a diagram for illustrating a reset write operation RESET write of storing reset data in a memory cell MC. The memory cell MC has a threshold voltage that changes depending on the direction of a current passing therethrough. For example, the threshold voltage of the memory cell MC is changed between a first level and a second level depending on the direction of a current passing therethrough. The first level is a level higher than the second level. When the level of the threshold voltage of the memory cell MC is the first level, the memory cell MC is in a reset state storing reset data. When the level of the threshold voltage of the memory cell MC is the second level, the memory cell MC is in a set state storing set data.

Referring to FIG. 1, the memory cell MC is electrically connected between a bit line BL and a word line WL. The reset write operation RESET write is an operation for changing the state of the memory cell MC to a reset state by storing reset data in the memory cell MC. For example, the memory cell MC is turned on by providing a first voltage to the word line WL and providing a second voltage to the bit line BL, and a current is allowed to flow from the word line WL to the bit line BL through the turned-on memory cell MC, thereby storing reset data in the memory cell MC. In an embodiment, the first voltage is a voltage at a higher level than the second voltage. For example, the first voltage is a positive voltage + and the second voltage is a negative voltage −.

FIG. 2 is a drawing for illustrating a set write operation SET write of storing set data in the memory cell MC.

Referring to FIG. 2, the memory cell MC is electrically connected between the bit line BL and the word line WL. The set write operation SET write is an operation for changing the state of the memory cell MC to a set state by storing set data in the memory cell MC. For example, the memory cell MC is turned on by providing the first voltage to the bit line BL and providing the second voltage to the word line WL, and a current is allowed to flow from the bit line BL to the word line WL through the turned-on memory cell MC, thereby storing set data in the memory cell MC. In an embodiment, the first voltage is a voltage of a higher level than the second voltage. For example, th first voltage is a positive voltage + and the second voltage is a negative voltage −.

In an embodiment, when the threshold voltage of the memory cell MC is at a first level higher than a second level, it can be said that the memory cell MC has changed to a state of storing reset data, that is, a reset state. When the threshold voltage of the memory cell MC is at the second level lower than the first level, it can be said that the memory cell MC has changed to a state of storing set data, that is, a set state.

That is, the threshold voltage level of the memory cell MC storing reset data is higher than the threshold voltage level of the memory cell MC storing set data.

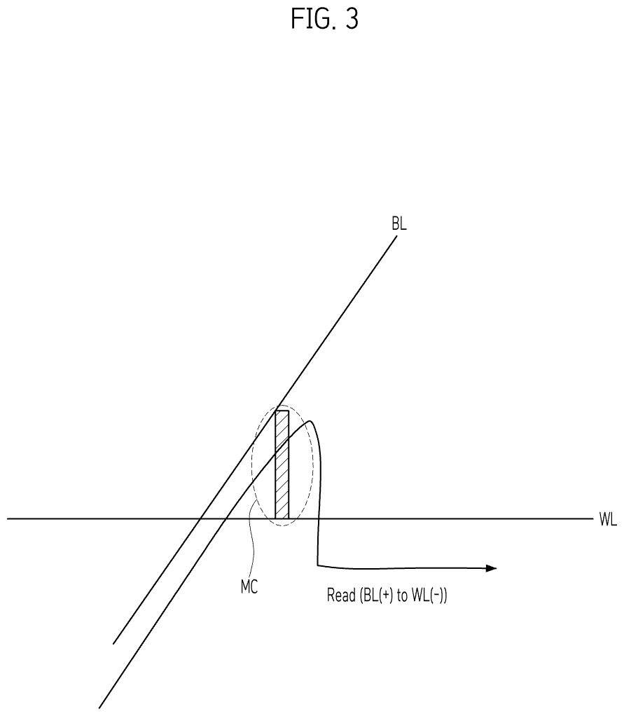

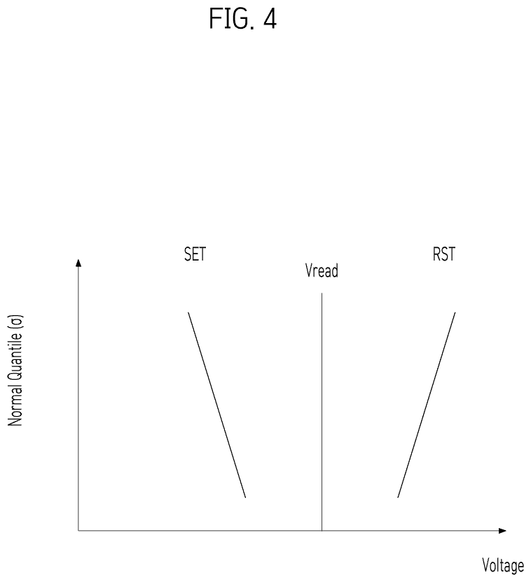

FIGS. 3 and 4 are diagrams for illustrating a read operation of a memory apparatus in accordance with an embodiment of the present disclosure.

Referring to FIG. 3, the read operation of the memory apparatus is an operation of determining whether the memory cell MC is turned on by providing a first voltage to the bit line BL and providing a second voltage to the word line WL. In such a case, a level difference between the voltages provided to the bit line BL and the word line WL during the read operation corresponds to a level between a threshold voltage of the memory cell in a set state and a threshold voltage of the memory cell in a reset state. That is, the level difference between the voltages provided to the bit line BL and the word line WL during the read operation corresponds to the level of a read voltage.

FIG. 4 is a drawing for illustrating a read operation of the memory cell MC that is converted to a reset state or a set state.

Referring to FIG. 4, the threshold voltage level of the memory cell MC in the set state SET is lower than the threshold voltage level of the memory cell MC in the reset state RST.

In an embodiment, during the read operation, a read voltage Vread is provided to the memory cell MC, and data stored in the memory cell MC is determined based on whether the memory cell MC is turned on. In such a case, a level difference between voltages applied to the bit line BL and the word line WL corresponds to the level of the read voltage Vread. That is, the level of the read voltage Vread is higher than the threshold voltage level of the memory cell MC in the set state SET and lower than the threshold voltage level of the memory cell MC in the reset state RST.

Accordingly, during the read operation, the memory cell MC in the set state SET to which the read voltage Vread is provided is turned on because a voltage higher than the threshold voltage is provided to the memory cell MC. In other words, when the read voltage Vread having a level higher than that of the threshold voltage of the memory cell MC in the set state SET is applied to the memory cell MC, the memory cell MC is turned on. On the other hand, during the read operation, the memory cell MC in the reset state RST to which the read voltage Vread is provided is turned off because a voltage lower than the threshold voltage is provided to the memory cell MC. In other words, when the read voltage Vread having a level lower than that of the threshold voltage of the memory cell MC in the reset state RESET is applied to the memory cell MC, the memory cell MC is turned off. Because substantially no current flows through the turned-off memory cell whereas a current flows through the turned-on memory cell, data stored in the memory cell MC is determined by sensing the voltage or current of one of the bit line BL and the word line WL during the read operation.

Accordingly, during the read operation, data stored in the memory cell MC is determined by providing the read voltage Vread to the memory cell MC.

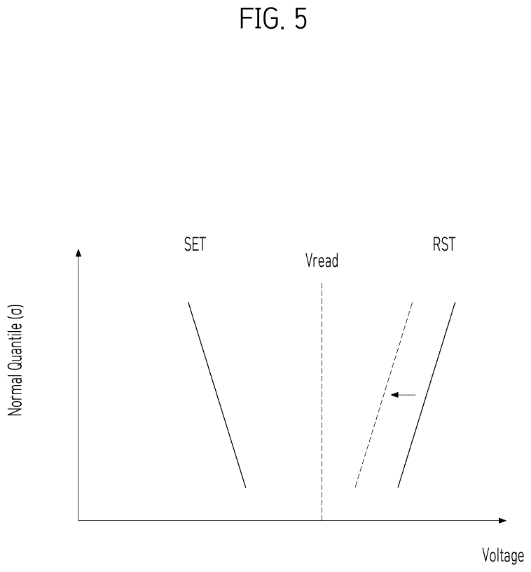

FIG. 5 is a diagram for illustrating a change in a threshold voltage of a memory cell due to a read operation of the memory apparatus in accordance with an embodiment of the present disclosure.

In an embodiment, the reset write operation RESET write of FIG. 1 is an operation for changing the state of the memory cell MC to the reset state RST, and is an operation for causing a current to flow from the word line WL to the bit line BL through the memory cell MC.

In an embodiment, the set write operation SET Write of FIG. 2 is an operation for changing the state of the memory cell MC to the set state SET state, and is an operation for causing current to flow from the bit line BL to the word line WL through the memory cell MC.

In an embodiment, the read operation Read of FIG. 3 is an operation for determining data stored in the memory cell MC, and is an operation for determining whether there is a current flowing from the bit line BL to the word line WL through the memory cell MC.

Referring to FIG. 5, as the number of times the read operation is performed increases, the threshold voltage level of the memory cell MC in the reset state RST may decrease. Without wishing to be bound by theory, this may be because the direction of a current passing through the memory cell MC during the reset write operation RESET write and the direction of a current passing through the memory cell MC during the read operation Read are opposite to each other.

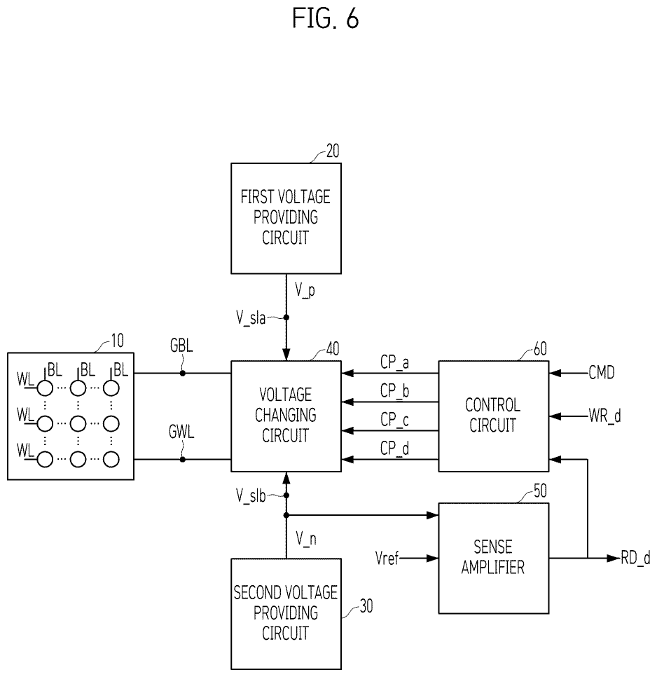

FIG. 6 is a diagram for illustrating configuration of a memory apparatus in accordance with an embodiment of the present disclosure.

Referring to FIG. 6, the memory apparatus includes a cell array 10, a first voltage providing circuit 20, a second voltage providing circuit 30, a voltage changing circuit 40, a sense amplifier 50, and a control circuit 60.

In an embodiment, the cell array 10 includes at least one memory cell MC electrically connected between a bit line BL and a word line WL. The bit line BL is electrically connected to a global bit line GBL, and the word line WL is electrically connected to a global word line GWL. For example, the bit line BL is electrically connected to or disconnected from the global bit line GBL on the basis of an address (not illustrated). The word line WL is also electrically connected to or disconnected from the global word line GWL on the basis of an address (not illustrated).

In an embodiment, the first voltage providing circuit 20 provides a first voltage V_p to the voltage changing circuit 40 through a first voltage line V_sla.

In an embodiment, the second voltage providing circuit 30 provides a second voltage V_n to the voltage changing circuit 40 through a second voltage line V_slb. In an embodiment, a level of the first voltage V_p is higher than a level of the second voltage V_n. For example, the first voltage V_p is a positive voltage and the second voltage V_n is a negative voltage.

In an embodiment, the voltage changing circuit 40 provides the first voltage V_p to one of the global bit line GBL and the global word line GWL on the basis of a first polarity conversion control signal CP_a, a second polarity conversion control signal CP_b, a third polarity conversion control signal CP_c, and a fourth polarity control signal CP_d, and provides the second voltage V_n to the other one of the global bit line GBL and the global word line GWL. For example, when the voltage changing circuit 40 provides the first voltage V_p to the global bit line GBL on the basis of the first to fourth polarity conversion control signals CP_a to CP_d, the voltage changing circuit 40 provides the second voltage V_n to the global word line GWL. In addition, when the voltage changing circuit 40 provides the first voltage V_p to the global word line GWL on the basis of the first to fourth polarity conversion control signals CP_a to CP_d, the voltage changing circuit 40 provides the second voltage V_n to the global bit line GBL.

In an embodiment, during a read operation, the sense amplifier 50 determines data stored in the memory cell MC. For example, during the read operation, the sense amplifier 50 determines data stored in the memory cell MC by comparing the level of the second voltage line V_slb and the level of the reference voltage Vref, and outputs a determination result as read data RD_d. More specifically, the sense amplifier 50 outputs a signal at a specific level (for example, a high level) as the read data RD_d during the read operation. For example, when the data stored in the memory cell MC is set data, the sense amplifier 50 outputs a signal of a specific level (e.g., a first level) as the read data RD_d, and when the data stored in the memory cell MC is reset data, the sense amplifier 50 changes the specific level and outputs the signal at the changed level (e.g., a second level) as the read data RD_d. That is, when the data of the memory cell MC is the set data, the sense amplifier 50 maintains the level of the signal output as the read data RD_d, and when the data of the memory cell MC is reset data, the sense amplifier 50 changes the level of the signal output as the read data RD_d, for example, changes the level from a high level to a low level. In other words, when the data of the memory cell MC is the set data, the sense amplifier 50 maintains the first level of the signal output as the read data RD_d, and when the data of the memory cell MC is reset data, the sense amplifier 50 changes the first level (e.g., a high level) to the second level (e.g., a low level) of the signal output as the read data RD_d.

In an embodiment, the control circuit 60 generates the first to fourth polarity conversion control signals CP_a to CP_d on the basis of a command CMD, write data WR_d, and the read data RD_d, and provides the first to fourth polarity conversion control signals CP_a to CP_d to the voltage changing circuit 40.

For example, when the command CMD is a write command, the control circuit 60 generates the first to fourth polarity conversion control signals CP_a to CP_d on the basis of the write data WR_d. More specifically, when the command CMD is a write command and the write data WR_d is reset data, the control circuit 60 provides the first to fourth polarity conversion control signals CP_a to CP_d to the voltage changing circuit 40 so that the first voltage V_p is provided to the global word line GWL and the second voltage V_n is provided to the global bit line GBL.

In addition, when the command CMD is a write command and the write data WR_d is set data, the control circuit 60 provides the first to fourth polarity conversion control signals CP_a to CP_d to the voltage changing circuit 40 so that the first voltage V_p is provided to the global bit line GBL and the second voltage V_n is provided to the global word line GWL.

On the other hand, when the command CMD is a read command, the control circuit 60 generates the first to fourth polarity conversion control signals CP_a to CP_d on the basis of the read data RD_d.

For example, when the command CMD is a read command and the read data RD_d is set data, the control circuit 60 provides the first to fourth polarity conversion control signals CP_a to CP_d to the voltage changing circuit 40 so that the first voltage V_p is provided to the global bit line GBL and the second voltage V_n is provided to the global word line GWL.

In addition, when the command CMD is a read command and the read data RD_d is reset data, the control circuit 60 provides the first to fourth polarity conversion control signals CP_a to CP_d to the voltage changing circuit 40 so that the first voltage V_p is provided to the global bit line GBL and the second voltage V_n is provided to the global word line GWL until the reset data is output from the sense amplifier 50, and, when the reset data is output from the sense amplifier 50, the first voltage V_p is provided to the global word line GWL and the second voltage V_n is provided to the global bit line GBL. In other words, when the sense amplifier 50 generates an output signal indicative of the reset data in the memory cell MC by changing a first level of the output signal to a second level, the voltage changing circuit 40 may provide the first voltage V_p to the global word line GWL and the second voltage V_n to the global bit line GBL to apply a reverse pulse to the memory cell MC. In some embodiments, a level of the first voltage V_p, or a level of the second voltage V_n, or both may be adjusted to sufficiently increase an amplitude of the reverse pulse to turn on the memory cell MC when the reverse pulse is applied thereto. For example, the reverse pulse may have an amplitude greater than an amplitude of a read pulse that has been applied to the memory cell MC before the sense amplifier 50 generates an output signal indicative of the reset data in the memory cell MC. As a result, a decreased threshold voltage of the memory cell MC in the reset state RST due to repetitive read operations may be sufficiently recovered to ensure storage reliability of the memory cell MC. In an embodiment, when the sense amplifier 50 generates an output signal indicative of the reset data in the memory cell MC, the first voltage providing circuit 20 may adjust a level of the first voltage V_p, or the second voltage providing circuit 30 may adjust a level of the second voltage V_n, or both, in response to the output signal. As a result, the voltage changing circuit 40 may provide the adjusted first voltage V_p to the global word line GWL and the adjusted second voltage V_n to the global bit line GBL to apply a reverse pulse having an amplitude increased compared to that of the read pulse to the memory cell MC.

In this way, because the voltage changing circuit 40, the sense amplifier 50, and the control circuit 60 access voltages provided to the global bit line GBL and the global word line GWL, respectively, on the basis of a read command and read data, the voltage changing circuit 40, the sense amplifier 50, and the control circuit 60 may be referred to as an access circuit. An operation, in which the first voltage V_p is provided to the global bit line GBL and the second voltage V_n is provided to the global word line GWL during a read operation under the control of the access circuit, and thus the first voltage V_p and the second voltage V_n are provided to both ends of the memory cell MC, corresponds to an operation of providing a read pulse to the memory cell MC. In addition, an operation, in which the second voltage V_n is provided to the global bit line GBL and the first voltage V_p is provided to the global word line GWL during a read operation under the control of the access circuit, and thus the second voltage V_n and the first voltage V_p are provided to both ends of the memory cell MC, corresponds to an operation in which a reverse pulse is provided to the memory cell MC. In some embodiments, an access circuit performs a read operation on a memory cell (e.g., the memory cell MC in FIG. 6) among a plurality of memory cells in a cell array (e.g., the cell array 10 in FIG. 6). Such an access circuit may determine data stored in the memory cell and selectively apply a reverse pulse to the memory cell based on the determined data. For example, the access circuit may apply a read pulse to the memory cell to determine the data stored in the memory cell, and apply the reverse pulse to the memory cell when the data of the memory cell is determined as reset data. Specifically, the reverse pulse has a polarity opposite to a polarity of the read pulse and has an amplitude sufficiently great to ensure that the memory cell is turned on. For example, the reverse pulse may have an amplitude greater than that of the read pulse. As a result, a threshold voltage of the memory cell in the reset state may be sufficiently recovered to ensure storage reliability of the memory cell. For example, when the data of the selected memory cell is determined as the reset data, the access circuit consecutively provides the read pulse and the reverse pulse to the selected memory cell.

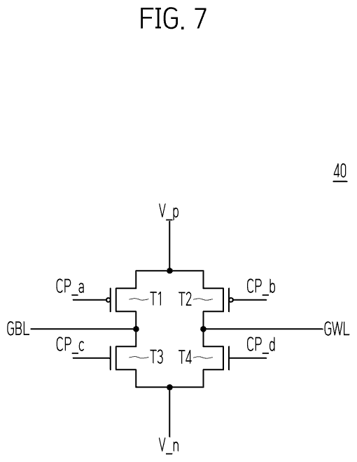

FIG. 7 is a diagram for illustrating configuration of a voltage changing circuit of a memory apparatus in accordance with an embodiment of the present disclosure. However, the configuration of the voltage changing circuit of the memory apparatus is not limited to the configuration of FIG. 7, and may vary according to embodiments.

Referring to FIG. 7, the voltage changing circuit 40 includes first to fourth transistors T1 to T4. In the embodiment of FIG. 7, the first and second transistors T1 to T2 that provide the first voltage V_p to one of the global bit line GBL and the global word line GWL are P-type transistors. In addition, the third and fourth transistors T3 to T4 that provide the second voltage V_n to one of the global bit line GBL and the global word line GWL are N-type transistors.

In an embodiment, the first transistor T1 receives the first polarity conversion control signal CP_a through a control terminal (e.g., a gate) thereof and receives the first voltage V_p through a first terminal (e.g., a source) thereof.

In an embodiment, the second transistor T2 receives the second polarity conversion control signal CP_b at through a control terminal (e.g., a gate) thereof and receives the first voltage V_p through a first terminal (e.g., a source) thereof. In such a case, the sources of the first and second transistors T1 and T2 are commonly connected to each other, and the first voltage V_p is applied to a node at which the sources are commonly connected to each other.

In an embodiment, the third transistor T3 receives the third polarity conversion control signal CP_c through a gate thereof and receives the second voltage V_n through a source thereof.

In an embodiment, the fourth transistor T4 receives the fourth polarity conversion control signal CP_d through a gate thereof and receives the second voltage V_n through a source thereof. In such a case, the sources of the third and fourth transistors T1 and T2 are connected to each other, and the second voltage V_n is applied to a node at which the sources are commonly connected to each other.

In an embodiment, a second terminal (e.g., a drain) of the first transistor T1 and a second terminal (e.g., a drain) of the third transistor T3 are commonly connected to the global bit line GBL. In addition, a second terminal (e.g., a drain) of the second transistor T2 and a second terminal (e.g., a drain) of the fourth transistor T4 are commonly connected to the global word line GWL.

The voltage changing circuit 40 configured described above in accordance with the embodiment of FIG. 7 can provide the first voltage V_p to one of the global bit line GBL and the global word line GWL, and provide the second voltage V_n to the other one of the global bit line GBL and the global word line GWL based on the first to fourth polarity conversion control signals CP_a to CP_d provided from the control circuit 60.

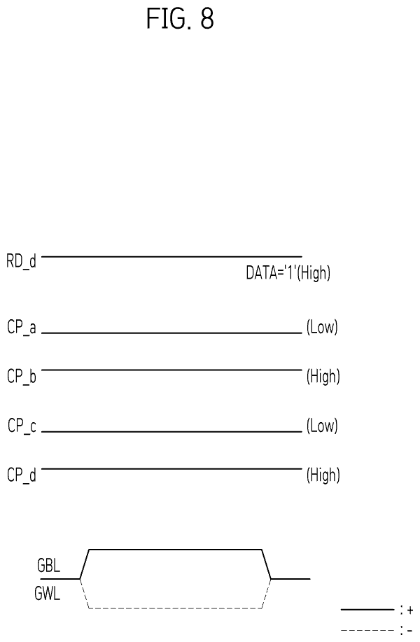

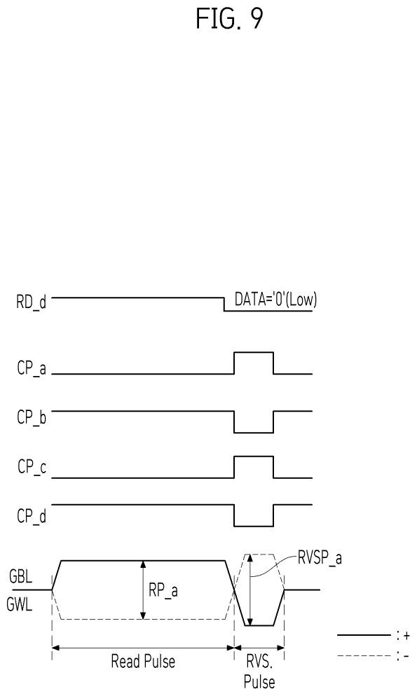

FIGS. 8 and 9 are timing diagrams for illustrating an operation of a memory apparatus in accordance with an embodiment of the present disclosure.

FIG. 8 is a timing diagram illustrating a case where read data is set data (e.g., 1, High) during a read operation by a read command.

Referring to FIG. 8, when the read command is received, the control circuit 60 enables the level of the first polarity conversion control signal CP_a to a low level, disables the level of the second polarity conversion control signal CP_b to a high level, disables the level of the third polarity conversion control signal CP_c to a low level, and enables the level of the fourth polarity conversion control signal CP_d to a high level.

Accordingly, between the first and second transistors T1 and T2, the first transistor T1 is turned on to provide the first voltage V_p to the global bit line GBL. In addition, between the third and fourth transistors T3 and T4, the fourth transistor T4 is turned on to provide the second voltage V_n to the global word line GWL.

Therefore, during the read operation, the voltage changing circuit 40 provides the first voltage V_p to the global bit line GBL and provides the second voltage V_n to the global word line GWL. For example, the first voltage V_p is a positive voltage + and the second voltage V_n is a negative voltage−.

In an embodiment, the first voltage V_p is transmitted to the bit line BL through the global bit line GBL, and the second voltage V_n is transmitted to the word line WL through the global word line GWL. The memory cell MC is turned on or off by receiving the first voltage V_p through the bit line BL and receiving the second voltage V_n through the word line WL. The sense amplifier 50 generates an output signal by comparing the voltage level of the second voltage line V_slb, to which the second voltage V_n is transmitted, with the level of a reference voltage Vref, and the output signal is transmitted to the control circuit 60 as the read data RD_d. In such a case, the level of the second voltage line V_slb is changed depending on whether the memory cell MC is turned on. In addition, the sense amplifier 50 maintains an output signal at a first level (e.g., a high level) or changes the high level of the output signal to a second level (e.g., a low level) depending on whether the memory cell MC is turned on.

In an embodiment, when data stored in the memory cell MC is set data, the output signal at a high level, that is, the level of the read data RD_d, is maintained.

In an embodiment, a voltage waveform of the global bit line GBL and the global word line GWL during the read operation is referred to as a read pulse. In such a case, a time interval during which the first voltage V_p is provided to the global bit line GBL and the second voltage V_n is provided to the global word line GWL during the read operation is a width (or a duration) of a read pulse. In addition, a voltage level difference between the global bit line GBL and the global word line GWL is the amplitude of the read pulse.

FIG. 9 is a timing diagram illustrating a case where read data is reset data (e.g., 0, Low) during a read operation by a read command.

Referring to FIG. 9, when the read command is received, the control circuit 60 enables the level of the first polarity conversion control signal CP_a to a low level, disables the level of the second polarity conversion control signal CP_b to a high level, disables the level of the third polarity conversion control signal CP_c to a low level, and enables the level of the fourth polarity conversion control signal CP_d to a high level.

Accordingly, between the first and second transistors T1 and T2, the first transistor T1 is turned on to provide the first voltage V_p to the global bit line GBL. In addition, between the third and fourth transistors T3 and T4, the fourth transistor T4 is turned on to provide the second voltage V_n to the global word line GWL.

Therefore, during the read operation, the voltage changing circuit 40 provides the first voltage V_p to the global bit line GBL and provides the second voltage V_n to the global word line GWL. For example, the first voltage V_p is a positive voltage +, and the second voltage V_n is a negative voltage −.

In an embodiment, the first voltage V_p is transmitted to the bit line BL through the global bit line GBL, and the second voltage V_n is transmitted to the word line WL through the global word line GWL. The memory cell MC is turned on or off by receiving the first voltage V_p through the bit line BL and receiving the second voltage V_n through the word line WL. The sense amplifier 50 generates an output signal by comparing the voltage level of the second voltage line V_slb, to which the second voltage V_n is transmitted, with the level of the reference voltage Vref, and the output signal is transmitted to the control circuit 60 as the read data RD_d. In such a case, the level of the second voltage line V_slb is changed depending on whether the memory cell MC is turned on. In addition, the sense amplifier 50 maintains an output signal at a first level (e.g., a high level) or changes the high level of the output signal to a second level (e.g., a low level) depending on whether the memory cell MC is turned on.

In an embodiment, when data stored in the memory cell MC is reset data, the high level of the output signal is changed to a low level. That is, the level of the read data RD_d is changed.

In an embodiment, when the level of the read data RD_d is changed, the control circuit 60 changes the levels of the first to fourth polarity conversion control signals CP_a to CP_d.

In an embodiment, when the level of the read data RD_d is changed, the low level of the first polarity conversion control signal CP_a is changed to a high level and maintained at the high level during a set time interval, the high level of the second polarity conversion control signal CP_b is changed to a low level and maintained at the low level during a set time interval, the low level of the third polarity conversion control signal CP_c is changed to a high level and maintained at the high level during a set time interval, and the high level of the fourth polarity conversion control signal CP_d is changed to a low level and maintained at the low level during a set time interval. For example, the set time interval may correspond to a duration of a reverse pulse RVS Pulse.

Therefore, as the levels of the first to fourth polarity conversion control signals CP_a to CP_d are changed, voltages applied to the global bit line GBL and the global word line GWL are also changed. For example, between the first and second transistors T1 and T2, the second transistor T2 is turned on to provide the first voltage V_p to the global word line GWL, and between the third and fourth transistors T3 and T4, the third transistor T3 is turned on to provide the second voltage V_n to the global bit line GBL. As a result, when the read data RD_d is reset data in the read operation, the control circuit 60 changes the levels of the first to fourth polarity conversion control signals CP_a to CP_d, and the voltage changing circuit 40 provides the first voltage V_p to the global word line GWL and provides the second voltage V_n to the global bit line GBL on the basis of the first to fourth polarity conversion control signals CP_a to CP_d whose levels have been changed.

As a result, a memory apparatus in accordance with an embodiment of the present disclosure can apply the first voltage V_p and the second voltage V_n to the global bit line GBL and the global word line GWL during the read operation, respectively, and when the read data RD_d is reset data, the memory apparatus can switch the first and second voltages V_p and V_n applied to the global bit line GBL and the global word line GWL for a set time interval.

That is, such a memory apparatus in accordance with an embodiment of the present disclosure can provide a read pulse Read Pulse during the read operation, and when the read data RD_d is reset data, the memory apparatus can provide a reverse pulse RVS Pulse having a polarity opposite to that of the read pulse Read Pulse. For example, when the read pulse Read Pulse is a pulse that provides the first voltage V_p to the global bit line GBL and provides the second voltage V_n to the global word line GWL, the reverse pulse RVS Pulse is a pulse that provides the second voltage V_n to the global bit line GBL and provides the first voltage V_p to the global word line GWL. In such a case, an amplitude RVSP_a of the reverse pulse RVS Pulse is equal to or greater than an amplitude RP_a of the read pulse Read Pulse. That is, a memory apparatus in accordance with an embodiment of the present disclosure switches voltages provided to the global bit line GBL and the global word line GWL when the read data RD_d is reset data in the read operation, and the voltage level difference between the global bit line GBL and the global word line GWL during a given period (e.g., the duration of the reverse pulse RVS Pulse) is equal to or greater than that before the switching.

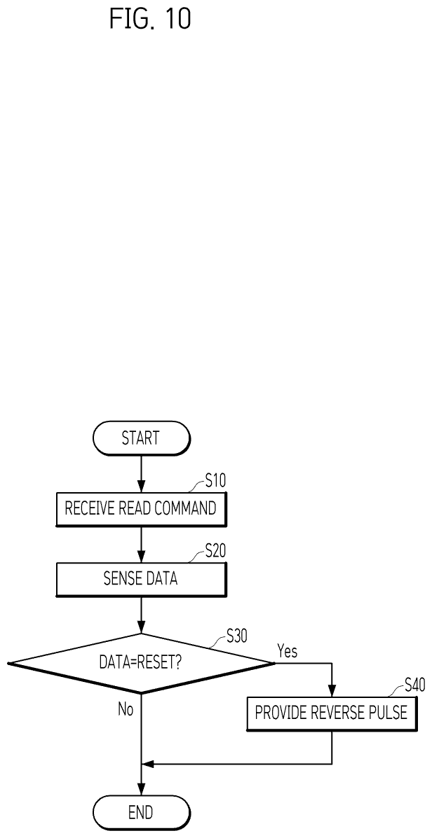

FIG. 10 is a flowchart for illustrating an operation of a memory apparatus in accordance with an embodiment of the present disclosure.

Referring to FIG. 10, the operation method of the memory apparatus includes receiving a read command at S10, sensing data at S20, determining data at S30, and providing a reverse pulse at S40.

In an embodiment, in receiving the read command at S10, the memory apparatus receives a read command. For example, the read command is provided to the control circuit 60.

In an embodiment, sensing the data at S20 includes providing the first voltage V_p and the second voltage V_n to the global bit line GBL and the global word line GWL, respectively, thereby determining data stored in the memory cell MC connected to a selected bit line BL and a selected word line WL. The global bit line GBL is electrically connected to the selected bit line BL, and the global word line GWL is electrically connected to the selected word line WL. Accordingly, the first voltage V_p and the second voltage V_n are applied to both ends of the memory cell MC, respectively. In such a case, the level of the second voltage line V_slb is changed depending on whether the memory cell MC is turned on, and the sense amplifier 50 senses a change in the level of the second voltage line V_slb and outputs read data RD. For example, when set data is stored in the memory cell MC, the sense amplifier 50 outputs an output signal maintained at a specific level as read data RD_d, and when reset data is stored in the memory cell MC, the sense amplifier 50 changes the level of an output signal at a specific level (or a first level) and outputs the output signal having a changed level (or a second level) as read data RD_d. That is, the level of the output of the sense amplifier 50, that is, the level of the read data RD_d, is not changed when set data is stored in the memory cell MC, and is changed when reset data is stored in the memory cell MC.

In an embodiment, determining data at S30 includes determining data stored in the memory cell MC. For example, determining data at S30 includes determining whether the data stored in the memory cell MC is reset data.

When it is determined, at S30, that the data stored in the memory cell MC is not reset data (No), that is, when the data stored in the memory cell MC is set data, the operation method of the memory apparatus is ended.

On the other hand, when it is determined, at S30, that the data stored in the memory cell MC is reset data (Yes), the process proceeds to S40 at which the reverse pulse is provided.

In an embodiment, providing the reverse pulse at S40 includes switching the first and second voltages V_p and V_n provided to the global bit line GBL and the global word line GWL in the data sensing step S20, respectively, and providing the switched voltages. For example, when sensing the data at S20 includes providing the first voltage V_p to the global bit line GBL and the second voltage V_n to the global word line GWL, providing the reverse pulse at S40 includes providing the second voltage V_n to the global bit line GBL and the first voltage V_p to the global word line GWL. In some embodiments, providing the reverse pulse at S40 may further include adjusting the first voltage V_p and the second voltage V_n, and providing the adjusted second voltage V_n to the global bit line GBL and the adjusted first voltage V_p to the global word line GWL.

A memory apparatus in accordance with an embodiment of the present disclosure can address issues associated with a change in a threshold voltage of a memory cell storing reset data due to repetitive read operations. Specifically, when data stored in the memory cell is determined as reset data in a read operation, voltages provided to both ends of the memory cell can be switched to compensate for the change in the threshold voltage of the memory cell.

Although some embodiments of the present disclosure have been described above with reference to the accompanying drawings, various embodiments of the present disclosure are not limited to the above-described embodiments. Various types of substitutions, modifications, and changes for the embodiments may be made, and it should be construed that these substitutions, modifications, and changes belong to embodiments of the present disclosure.

What is claimed is:

1. A memory apparatus comprising:
a cell array comprising a plurality of memory cells; and
an access circuit that performs a read operation on a memory cell among the plurality of memory cells,
wherein the access circuit determines data stored in the memory cell and selectively applies a reverse pulse to the memory cell based on the determined data of the memory cell.

2. The memory apparatus of claim 1, wherein the access circuit applies a read pulse to the memory cell to determine the data stored in the memory cell, and applies the reverse pulse to the memory cell when the data of the memory cell is determined as reset data.

3. The memory apparatus of claim 2, wherein the reverse pulse has a polarity opposite to a polarity of the read pulse.

4. The memory apparatus of claim 3, wherein the memory cell is electrically connected to each of a bit line and a word line, and
wherein, when the reverse pulse is applied to the memory cell, voltages provided to the bit line and the word line when the read pulse is applied to the memory cell are switched.

5. The memory apparatus of claim 3, wherein the access circuit applies the reverse pulse having an amplitude greater than that of the read pulse.

6. The memory apparatus of claim 5, wherein, when the data of the memory cell is determined as the reset data, the access circuit adjusts a level of the first voltage, a level of the second voltage, or both to apply the reverse pulse to the memory cell.

7. The memory apparatus of claim 3, wherein, when the data of the memory cell is determined as the reset data, the access circuit consecutively provides the read pulse and the reverse pulse to the memory cell.

8. The memory apparatus of claim 7, wherein the read pulse causes a first current to pass through the memory cell in a first direction, and
wherein the reverse pulse causes a second current to pass through the memory cell in a second direction different from the first direction.

9. The memory apparatus of claim 8, wherein the memory cell is electrically connected to each of a bit line and a word line,
wherein, when the first current passes through the memory cell in the first direction, the first current flows from the bit line to the word line through the memory cell, and
wherein, when the second current passes through the memory cell in the second direction, the second current flows from the word line to the bit line through the memory cell.

10. A memory apparatus comprising:
a cell array comprising at least one memory cell electrically connected between a bit line and a word line;
a voltage changing circuit that provides voltages to a global bit line electrically connected to the bit line and a global word line electrically connected to the word line; and
a control circuit that selects a voltage to be provided to the global word line and a voltage to be provided to the global bit line from the voltages by controlling the voltage changing circuit according to a command, write data, and read data.

11. The memory apparatus of claim 10, wherein the voltages comprise a first voltage and a second voltage having a lower level than the first voltage, and
wherein, when the command is a read command, the control circuit controls the voltage changing circuit so that the first voltage is provided to the global bit line and the second voltage is provided to the global word line to apply a read pulse to the memory cell.

12. The memory apparatus of claim 11, wherein, when the read data is determined as reset data while the first voltage is being provided to the global bit line and the second voltage is being provided to the global word line according to the read command, the control circuit controls the voltage changing circuit so that the first voltage is provided to the global word line and the second voltage is provided to the global bit line.

13. The memory apparatus of claim 11, further comprising:
a first voltage providing circuit providing the first voltage to the voltage changing circuit; and
a second voltage providing circuit providing the second voltage to the voltage changing circuit,
wherein, when the read data is determined as reset data, the first voltage providing circuit adjusts a level of the first voltage, or the second voltage providing circuit adjusts a level of the second voltage, or both, to apply a reverse pulse having an amplitude greater than an amplitude of the read pulse to the memory cell.

14. The memory apparatus of claim 11, wherein, when the command is a write command and the write data is reset data, the control circuit controls the voltage changing circuit so that the first voltage is provided to the global word line and the second voltage is provided to the global bit line.

15. The memory apparatus of claim 11, wherein, when the command is a write command and the write data is set data, the control circuit controls the voltage changing circuit so that the first voltage is provided to the global bit line and the second voltage is provided to the global word line.

16. An operation method of a memory apparatus, the operation method comprising:
receiving a read command to read a memory cell;
sensing data stored in the memory cell according to the read command;
determining whether the sensed data of the memory cell is reset data; and
providing a reverse pulse to the memory cell in response to determining that the data stored in the memory cell is the reset data.

17. The operation method of claim 16, wherein the sensing of the data comprises:
providing a first voltage to a global bit line and providing a second voltage to a global word line, the second voltage having a lower level than the first voltage.

18. The operation method of claim 17, wherein the providing of the reverse pulse to the memory cell comprises:
providing the second voltage to the global bit line and providing the first voltage to the global word line.

19. The operation method of claim 18, wherein the global bit line is electrically connected to a bit line,
wherein the global word line is electrically connected to a word line, and
wherein the memory cell is electrically connected between the bit line and the word line.

20. The operation method of claim 16, wherein the read command is a first read command and the memory cell is a first memory cell, the operation method further comprising:
receiving a second read command to read a second memory cell;
sensing data stored in the second memory cell according to the second read command;
determining whether the sensed data of the second memory cell is set data; and
determining not to apply the reverse pulse to the second memory cell in response to determining that the data of the second memory cell is the set data.
